(19) United States
(12) Patent Application Publication
(10) Pub. No.: US 2013/0082764 A1
(43) Pub. Date: Apr. 4, 2013

(54) APPARATUS AND METHOD TO COMBINE PIN FUNCTIONALITY IN AN INTEGRATED CIRCUIT

(71) Applicants: Paul Penzes, Irvine, CA (US); Love Kothari, Sunnyvale, CA (US); Ajat Hukkoo, Cupertino, CA (US); Mark Fullerton, Austin, TX (US); Veronica Alarcon, San Jose, CA (US); Zhongmin Zhang, Fremont, CA (US); Kerry Alan Thompson, Fort Collins, CO (US); Russell Radke, Fort Collins, CO (US)

(72) Inventors: Paul Penzes, Irvine, CA (US); Love Kothari, Sunnyvale, CA (US); Ajat Hukkoo, Cupertino, CA (US); Mark Fullerton, Austin, TX (US); Veronica Alarcon, San Jose, CA (US); Zhongmin Zhang, Fremont, CA (US); Kerry Alan Thompson, Fort Collins, CO (US); Russell Radke, Fort Collins, CO (US)

(73) Assignee: BROADCOM CORPORATION, Irvine, CA (US)

(21) Appl. No.: 13/250,677

(22) Filed: Sep. 30, 2011

(51) Int. Cl. G05F 3/02; H03B 1/00; G11C 5/14

(52) U.S. Cl. 327/540; 327/530; 327/558

(57) ABSTRACT

An apparatus and method are disclosed to combine pad functionality in an integrated circuit. A power, ground, or signal pad is connected to a power, ground, or signal source, respectively. The power, ground, or signal pad is additionally connected to an additional signal source, such as automatic test equipment in a testing environment. By temporarily disconnecting either the power, ground, or signal source, from the functional block within the integrated circuit to which the source is delivered, the same pad may pass in another signal to other portions of the integrated circuit. In the alternative, the same pad may pass in another signal to other portions of the integrated circuit without disconnecting the original signal by coupling the additional signal over the original signal. Further, combining pad functionality enables reuse of an input pad as an output pad for signals originating from within the integrated circuit.

### BACKGROUND

1. Field of Invention

The present invention relates generally to the combination of functionalities into a single pad to enable general purpose input/output while maintaining the existing pad count.

2. Related Art

While integrated circuits have become smaller, their functionality has concurrently increased. Pin count has become an increasingly expensive issue in the design and manufacture of integrated circuits due to chip packaging constraints, since there are now more functions and corresponding signals that must pass in and out of the integrated circuit.

Typically, an integrated circuit has dedicated pins, or pads, for test mode, General Purpose Input/Output (GPIO), dedicated input/output, power and ground, and other functionality as determined by the designer and/or manufacturer. One solution designers and manufacturers have developed to address the increasing cost of pin count in a chip package has been to apply pin multiplexing.

Pin multiplexing is typically applied to GPIO pins in an integrated circuit and requires a control pin or programmatic commands for switching from one pin function to another. Prior systems have enabled pin multiplexing at power up or during operation. For example, a multiplexer switches a GPIO pin interface at system start up, leaving those pins in that particular configuration until restarting the chip. Dynamic switching of pin function is possible, but is typically implemented through a controller that manages requests from various systems in the chip package. Such solutions have concentrated on multiplexing GPIO pads, which do not constitute all of the pads on a chip package. This leaves the other pads, such as power and ground pads, underutilized.

Thus, there is a need for an apparatus to utilize more existing pads for pad reuse than GPIO pads. Further aspects and advantages of the present invention will become apparent from the detailed description that follows.

### BRIEF DESCRIPTION OF THE DRAWINGS/FIGURES

The present invention is described with reference to the accompanying drawings. In the drawings, like reference numbers indicate identical or functionally similar elements. Additionally, the left most digit(s) of a reference number identifies the drawing in which the reference number first appears.

FIG. 1 illustrates a block diagram of an integrated circuit testing environment according to an exemplary embodiment of the present invention;

FIG. 2 illustrates a block diagram of a conventional pad configuration in an integrated circuit;

FIG. 3 illustrates a block diagram of a combined functionality pad configuration on an integrated circuit according to a first exemplary embodiment of the present invention;

FIG. 4 illustrates a block diagram of a combined functionality pad configuration on an integrated circuit according to a second exemplary embodiment of the present invention;

FIG. 5 illustrates a block diagram of a combined functionality pad configuration on an integrated circuit according to a third exemplary embodiment of the present invention;

FIG. 6 illustrates a block diagram of an alternative combined functionality pad configuration on an integrated circuit according to the third exemplary embodiment of the present invention;

FIG. 7 illustrates a block diagram of a combined functionality pad configuration on an integrated circuit according to a fourth exemplary embodiment of the present invention; and

FIG. 8 illustrates a method of utilizing the combined functionality pad on an integrated circuit according to an exemplary embodiment of the present invention.

The present invention will now be described with reference to the accompanying drawings. In the drawings, like reference numbers generally indicate identical, functionally similar, and/or structurally similar elements. The drawing in which an element first appears is indicated by the leftmost digit(s) in the reference number.

### DETAILED DESCRIPTION OF THE INVENTION

The following Detailed Description refers to accompanying drawings to illustrate exemplary embodiments consistent with the invention. References in the Detailed Description to “one exemplary embodiment,” “an exemplary embodiment,” “an example exemplary embodiment,” etc., indicate that the exemplary embodiment described may include a particular feature, structure, or characteristic, but every exemplary embodiment may not necessarily include the particular feature, structure, or characteristic. Moreover, such phrases are not necessarily referring to the same exemplary embodiment. Further, when a particular feature, structure, or characteristic is described in connection with an exemplary embodiment, it is within the knowledge of those skilled in the relevant art(s) to effect such feature, structure, or characteristic in connection with other exemplary embodiments whether or not explicitly described.

The exemplary embodiments described herein are provided for illustrative purposes, and are not limiting. Other exemplary embodiments are possible, and modifications may be made to the exemplary embodiments within the spirit and scope of the invention. Therefore, the Detailed Description is not meant to limit the invention. Rather, the scope of the invention is defined only in accordance with the following claims and their equivalents.

Embodiments of the invention may be implemented in hardware, firmware, software, or any combination thereof. Embodiments of the invention may also be implemented as instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic disk storage media; optical storage media; flash memory devices; electrical, optical, acoustical or other forms of propagated signals (e.g., carrier waves, infrared signals, digital signals, etc.), and others. Further, firmware, software, routines, instructions may be described herein as performing certain actions. However, it should be appreciated that such descriptions are merely for convenience and that such actions in fact result from computing devices, processors, controllers, or other devices executing the firmware, software, routines, instructions, etc.

The following Detailed Description of the exemplary embodiments will so fully reveal the general nature of the invention that others can, by applying knowledge of those skilled in relevant art(s), readily modify and/or adapt for various applications such exemplary embodiments, without undue experimentation, without departing from the spirit and scope of the present invention. Therefore, such adaptations and modifications are intended to be within the meaning and plurality of equivalents of the exemplary embodiments based upon the teaching and guidance presented herein. It is to be understood that the phraseology or terminology herein is for the purpose of description and not of limitation, such that the terminology or phraseology of the present specification is to be interpreted by those skilled in relevant art(s) in light of the teachings herein.

Exemplary Testing Environment

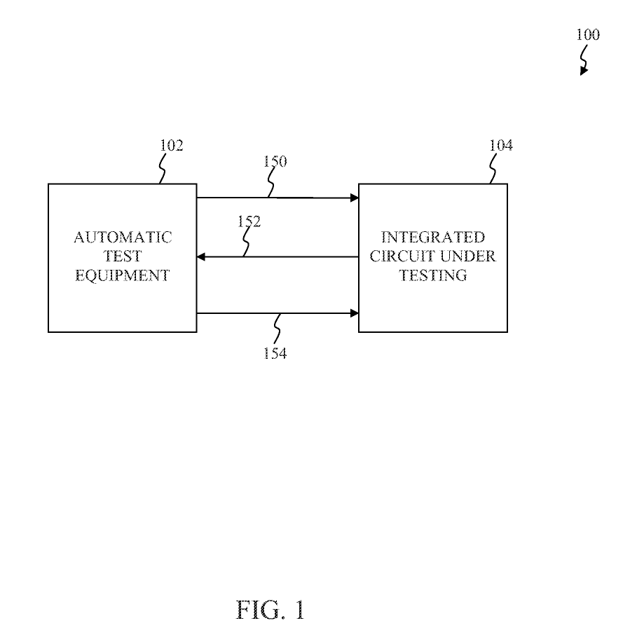

FIG. 1 illustrates a block diagram of an integrated circuit testing environment according to an exemplary embodiment of the present invention. Automatic test equipment (ATE) 102 interfaces with integrated circuit under testing (IUT) 104 to test different functionality of IUT 104. ATE 102 sends test mode signal 150 to IUT 104 to place IUT 104 into test mode. ATE 102 then sends test signal(s) 154 to IUT 104, to which IUT 104 responds with response test signal(s) 152.

IUT 104 may also receive test signal(s) 154 from a source besides ATE 102. IUT 104 may be any type of integrated circuit that typically undergoes testing before delivery to a customer or end user. IUT 104 may be any type of integrated circuit suited for testing as will be recognized by one skilled in the relevant art(s). Some specific examples include Systems-on-Chip (SoCs), printed circuit boards, microprocessors, or components of the same such as power management units, memory, controllers, and digital logic.

While the above and following discussion describes IUT 104 as being a circuit in testing environment 100, it should be understood that it is by way of example and should not be considered to limit the present invention to only that environment. As will become clear in the discussion below and as will be recognized by one skilled in the art(s), IUT 104 may be an integrated circuit or other type of circuit in any mode of operation, include under test and under regular operation.

Conventional Test Mode Pad Configuration

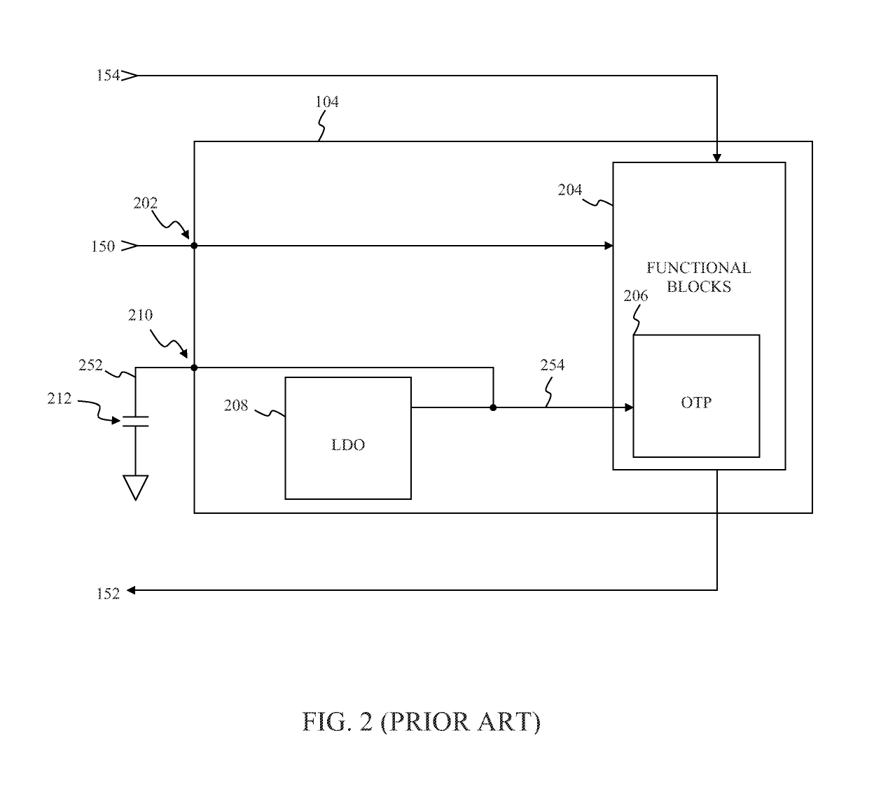

FIG. 2 illustrates a conventional test mode pad configuration in an integrated circuit. In FIG. 2, IUT 104 has a dedicated test mode pad 202. Dedicated test mode pad 202 receives the test mode signal 150 from ATE 102, which by default is typically asserted high. When ATE 102 seeks to place IUT 104 into test mode, ATE 102 outputs test mode signal 150 high. IUT 104 receives test mode signal 150 at dedicated test mode pad 202 and passes the test mode signal 150 to the functional blocks 204. IUT 104 thereby enters test mode.

When in test mode, IUT 104 receives test signal(s) 154 through other dedicated pads at the functional blocks 204. The functional blocks 204 output the response test signal(s) 152 which the ATE 102 then receives. When ATE 102 seeks to remove IUT 104 from test mode, ATE 102 de-asserts test mode signal 150 such that IUT 104 exits test mode.

In this conventional configuration, IUT 104 has a separate, dedicated compensation capacitor pad 210. Compensation capacitor pad 210 has compensation capacitor 212 attached to provide current 252 to low dropout regulator 208. Low dropout regulator 208 provides regulated voltage 254 to one-time programmable memory 206 within functional blocks 204. In this manner, compensation capacitor pad 210 provides compensation current 252 from compensation capacitor 212 to low dropout regulator 208 as the need may arise during operation of IUT 104.

The dedicated test mode pad 202 therefore remains unused except for periods of time when the IUT 104 is tested, which is a relatively short period of time compared to the IUT 104's anticipated operational life.

### A First Exemplary Embodiment of Combined Pad Functionality

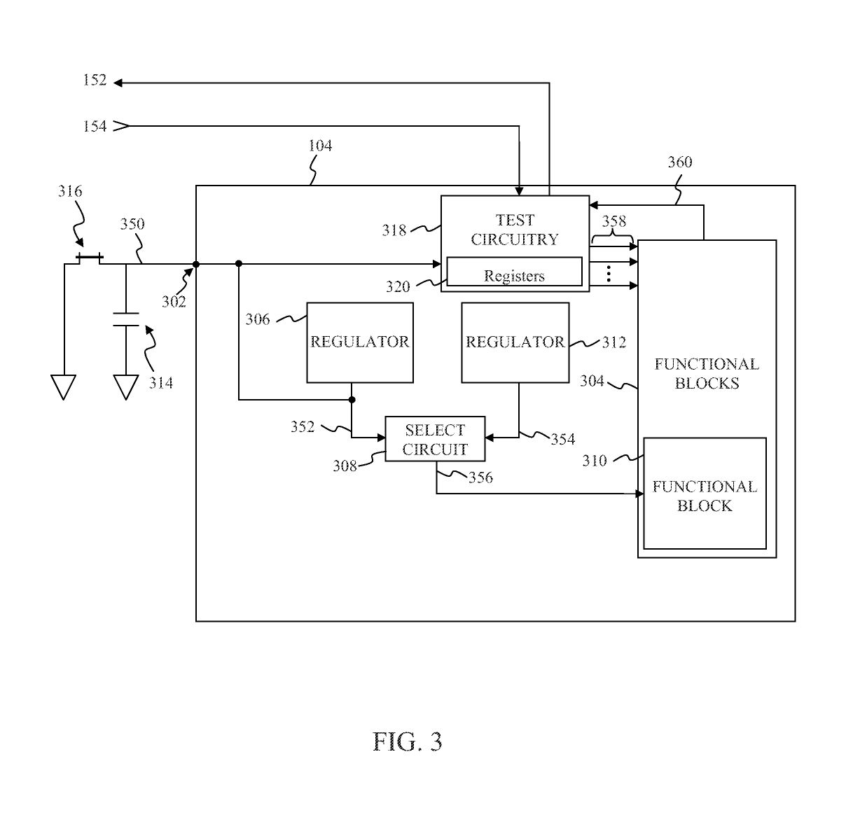

FIG. 3 illustrates a block diagram of a combined functionality pad configuration on an integrated circuit according to a first exemplary embodiment of the present invention. In FIG. 3, IUT 104 combines the dedicated compensation capacitor pad 210 and the dedicated test mode pad 202 from FIG. 2 into a combined pad 302. In this configuration, IUT 104 will only enter test mode when the input 350 is asserted low—in other words, when test mode signal 150 is asserted low. This occurs when the combined pad is shorted to ground, for example by inserting jumper 316 between the combined pad 302 and ground.

In functional mode, combined pad 302 is connected to compensation capacitor 314, in configuration and function as discussed above for FIG. 2. Input 350 is high, allowing compensation capacitor 314 to provide compensating current as input 350 through combined pad 302 to a first regulator 306. First regulator 306 provides a first regulated voltage 352 to a select circuit 308. The other input to select circuit 308 is a second regulated voltage 354 provided by second regulator 312. Select circuit 308 operates to select a regulated voltage to provide as output voltage 356 to functional block 310. IUT 104 may include more voltage regulators as inputs to select circuit 308 than first regulator 306 and second regulator 312.

Select circuit 308 may be, for example, a multiplexer that switches between the two regulated voltage inputs. The first and second regulators 306 and 312, respectively, may be any type of voltage regulator. When IUT 104 includes more voltage regulators as inputs to select circuit 308, select circuit 308 would have additional logic to enable switching between the different regulated voltage inputs. First regulator 306 and second regulator 312 may be, for example, low dropout regulators. Functional block 310 may be configured for any functionality, for example a one-time programmable memory as discussed above in FIG. 2.

While in functional mode, the combined pad 302 only provides compensation current as input 350 when the first regulator 306 requires it. There is no dedicated pad separate from combined pad 302 that will place IUT 104 into test mode. IUT 104 will not respond to test signal(s) 154 when it is in functional mode. This is the case because combined pad 302 is not at ground, as IUT 104 requires in this configuration to enter test mode.

When it is desirable to place IUT 104 into test mode, combined pad 302 is tied directly to ground. This is accomplished, for example, by using jumper 316. As will be recognized by those of skill in the relevant art(s), other ways may be used to tie combined pad 302 to ground, such as a switch, direct connection, and so on. When this occurs, input 350 becomes low and test mode is therefore asserted. Current is no longer provided via input 350, so the first regulator 306 stops providing the first regulated voltage 352 to select circuit 308. Functional block 310 turns off and remains off until the input 350 at combined pad 302 becomes high again.

Because combined pad 302 is tied to ground, the functional blocks 304 are placed into test mode. When this happens, ATE 102 may apply test signal(s) 154. Test circuitry 318 receives test signal(s) 154, which then outputs IUT-specific signals 358 to the functional blocks 304. Test circuitry 318 operates as an interface between the test signal(s) 154 sent from ATE 102 and the functional blocks 310 of IUT 104. In one example, Test circuitry 318 operates as a JTAG interface that decodes test signal(s) 154 from ATE 102 into specific signals (IUT-specific signals 358) that instruct the various functional blocks 304 what to do in test mode. JTAG is a protocol added to the IUT 104 that allows multiple blocks from among functional blocks 414 to be connected in a daisy chain so a test probe only connects to one port to test IUT 104.

After the functional blocks 304 specified by the test circuitry 318 have received the IUT-specific signals 358, the functional blocks 304 specified by the test circuitry 318 output internal response signal(s) 360 to the testing circuitry 318. Test circuitry 318 serves as an interface for the internal response signal(s) 360 and the response test signal(s) 152 expected by ATE 102. ATE 102 receives the response test signal(s) 152 and processes them to verify whether the IUT works as intended. To exit test mode, the jumper 316 is disconnected again, returning input 350 at combined pad 302 high.

When input 350 at combined pin 302 goes low to place IUT 104 into test mode, register 320 is enabled, and is only enabled with input 350 goes low and remains enabled while IUT 104 is in test mode. Registers 320 may include one or more shift registers that are used as part of the test circuitry 318 as the JTAG interface, as well as permanent registers. ATE 102 may instruct IUT 104 to remain in test mode even when input 350 at combined pad 302 returns high by disconnecting jumper 316. In this situation, register 320 sets one or more bits in a shift register, which is then set in a permanent register. This keeps test circuitry 318 enabled and IUT 104 in test mode for further testing. Functional block 310 remains off even when input 350 at combined pad 302 returns high, unless test circuitry 318 instructs functional block 310 to turn on. When testing is complete, jumper 316 is again used to tie combined pad 302 to ground. This renders input 350 at combined pad 302 low, which signals to IUT 104 to exit test mode. IUT 104 exits out of test mode by clearing the bit(s) in registers 320 that had been set for test mode when input 350 at combined pad 302 returns high (by disconnecting jumper 316).

The functional blocks 304 include a plurality of blocks that perform different functions. Functional block 310 is an exemplary functional block selected from among the plurality of blocks contained within the functional blocks 304. It should be understood that FIG. 3, as well as the rest of the figures discussed herein, are high-level block diagrams only which do not illustrate all of the connections that actually exist between blocks.

### A Second Exemplary Embodiment of Combined Pad Functionality

This principle of combining functionality to a pad may be extended beyond removing the need for a dedicated test mode pad, such as the dedicated test mode pad 202 of FIG. 2, to combining the functionality of other pads for other signals.

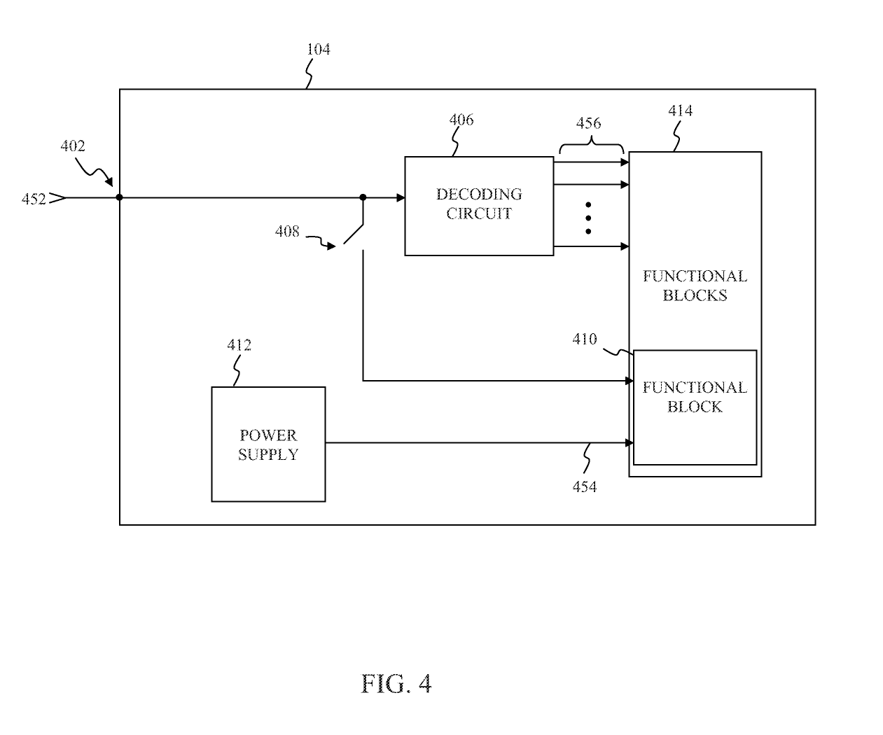

FIG. 4 illustrates a block diagram of a combined functionality pad configuration according to a second exemplary embodiment of the present invention. In particular, FIG. 4 illustrates the ability to combine other functionality besides the test mode signal and the compensation capacitor, as was shown in FIG. 3.

According to the second exemplary embodiment of the present invention, IUT 104 can pass in sets of data through a combined pad 402, typically a power or ground pad. IUT 104 includes a switch 408 that is off by default. Switch 408 may be, for example, a transistor switch. Functional block 410 within IUT 104 receives power as voltage 452 from combined pad 402 when switch 408 is on. When switch 408 is off, functional block 410 may receive power from an alternative power supply 412 through alternative voltage 454. Switch 408 may be controlled by a processor from the functional blocks 414. In addition, switch 408 may be controlled by a signal from a JTAG interface, not shown in FIG. 4.

When IUT 104 is powered on from an off state, switch 408 is off and therefore voltage 452 from combined pad 402 is not provided to functional block 410. In this situation, combined pad 402 may be used to pass in a sequence of data such as test signal(s) 154. Test signal(s) 154 pass in through combined pad 402 and are received at decoding circuit 406. Decoding circuit 406 provides decoded signal(s) 456 to the functional blocks 414. As discussed above for FIG. 3, functional block 410 is exemplary of the plurality of functional blocks contained within the functional blocks 414. Therefore, functional block 410 is capable of receiving any signals that the functional blocks 414 receive, either directly or indirectly.

Decoded signal(s) 456 may be, for example, test signal(s) 154 provided by ATE 102 in an exemplary integrated circuit testing environment. In such a situation, the IUT 104 provides response test signal(s) 152 through other dedicated pads on the IUT 104, which are not shown in FIG. 4. Typically, combined pad 402, when passing test signal(s) 154, will not operate as a bidirectional pad. Response test signals 152 will be output, as indicated above, through other dedicated pads for receipt at the ATE 102.

Combined pad 402 may also operate as a bidirectional pad when switch 408 is turned off. When configured to operate as a bidirectional pad, the IUT 104 may need to detect that it is in test mode. The IUT 104 may do so, for example, by monitoring the pad that receives the test mode signal. If the test mode signal is asserted low, the IUT 104 will recognize that it is in test mode when the test mode signal is low for a predetermined period of time. Conversely, if the test mode signal is asserted high, the IUT 104 will recognize that it is in test mode with the test mode signal is high for a predetermined period of time. Once IUT 104 recognizes it is in test mode, it may stop monitoring the test mode signal and allow data to be output via the combined pad 402 as well. To exit test mode, IUT 104 has another pad that receives a signal instructing the IUT 104 to exit test mode. Data transmission out of the combined pad 402 ends upon receipt of this signal. When this occurs, switch 408 may be turned on as well, causing voltage 452 to provide power to the functional block 410 again and inhibiting any transmission of data through combined pad 402 until switch 402 is turned off again.

Combined pad 402 is not restricted to providing a sequence of data such as test signal(s) 154 only at power up of the IUT 104. Switch 408, off by default, may be turned off again at any time during operation as directed by the controlling processor in the functional blocks 414 or JTAG signal. Any time switch 408 is turned off, IUT 104 may pass a sequence of data such as test signal(s) 154 through combined pad 402 to the functional blocks 414. In such situations, the functional block 410 affected by turning off switch 408 will continue receiving power by alternative power supply 412.

### A Third Exemplary Embodiment of Combined Pad Functionality

While the above contemplates inputting either a power or a data sequence through a combined pad, it is also possible to provide both power and a data signal at the same time.

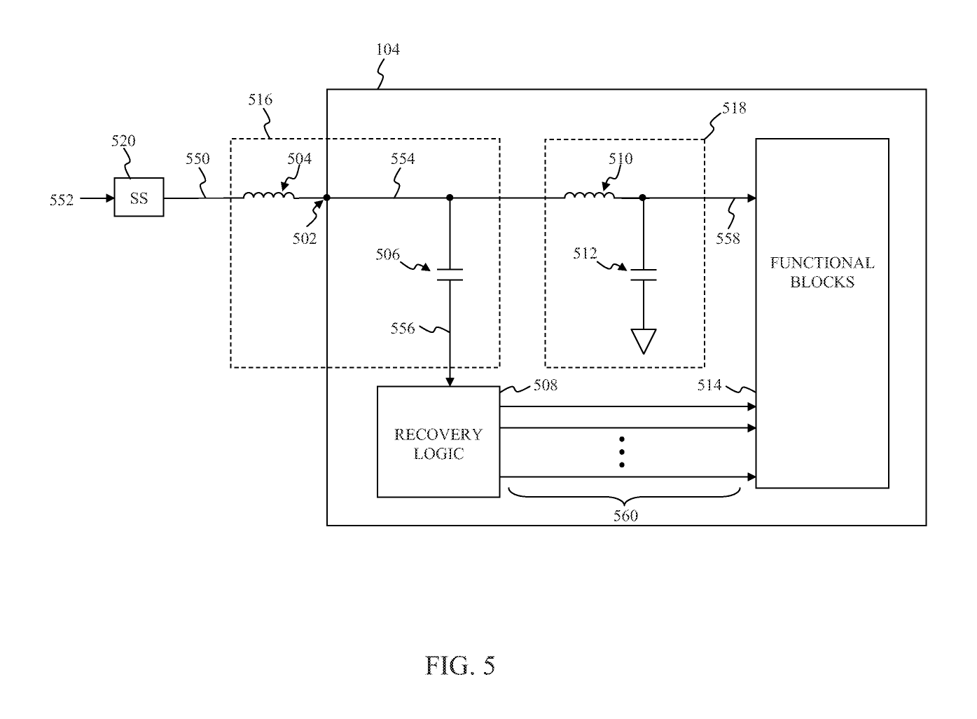

FIG. 5 illustrates a block diagram of a combined functionality pad configuration according to a third exemplary embodiment of the present invention. The configuration of IUT 104 in FIG. 5 allows the transmission of a data signal through a pad at the same time that the pad is being used for its originally designed purpose.

Combined pad 502 may be a power pad, ground pad, dedicated signal pad, or GPIO pad. For example, combined pad 502 may be a power pad as shown in FIG. 5. When this is the case, the input signal 550 normally expected at combined pad 502 is an input voltage provided by an external power source, depicted in FIG. 5 as signal source 520. A second input signal 552, such as a data signal, may be input through combined pad 502 while the input voltage 550 is maintained at the combined pad 502. Maintenance of both signals at the combined pad 502 at the same time is possible by A/C coupling the input signal 552 to the signal line while maintaining input voltage 550, provided by signal source 520 configured as a power source.

A/C coupling occurs when the input signal 552 is modulated at a frequency significantly higher than the frequency of the input signal 550. For example, the input signal 550, here an input voltage, typically operates at 50 Megahertz (MHz). A typical integrated circuit is configured to recognize input signals modulated at or around that frequency. When A/C coupling an additional input signal 552 onto the input signal 550 line, input signal 552 is modulated at a higher frequency, such as in the tens to hundreds of Gigahertz (GHz) range. Thus, when input signal 552, modulated at tens to hundreds of GHz, is input on the combined pad 502 with input signal 550, such as an input voltage, both signals may be distinctly recovered as described below.

IUT 104 includes a high pass filter 516 and a low pass filter 518 to recover the input signal 552 and input signal 550, respectively. As shown in FIG. 5, high pass filter 516 includes inductance 504 external to the IUT 104 and capacitance 506 within IUT 104. In one embodiment, inductance 504 is optional as would be apparent to those skilled in the art. Within the low pass filter, capacitance 506 is much smaller than capacitance 512. When the high frequency input signal 552 reaches high pass filter 516, it is allowed to pass as input A/C signal 556 into recovery logic 508. Recovery logic 508 includes circuitry necessary to convert the input A/C signal 556 to logic signals 560 that are then passed on to the appropriate blocks within the functional blocks 514. High pass filter 516 does not allow the lower frequency input signal 550 to pass on to recovery logic 508 as input A/C signal 556. Instead, the lower frequency input signal 550 passes on as input low frequency signal 554 to the low pass filter 518.

Low pass filter 518 serves, among other things, to remove any remaining high frequency transients that made it through high pass filter 516 so that the functional blocks 514 receives a clean input signal 558. Low pass filter 518 may include, for example as shown in FIG. 5, an inductance 510 followed by a capacitance 512. Capacitance 512 has a much larger capacitance than capacitance 506 in the high pass filter. Clean input signal 558 is all that remains of the combined signals 550 and 552 originally input at combined pad 502. In this configuration, it may be desirable to have inductance 510 as little as possible while having capacitance 512 as large as possible.

In the configuration depicted in FIG. 5, IUT 104 may best be suited to receive slower speed signals as input signal 552 due to the inductance in the filters 516 and 518. Examples of low speed signals include test signals (such as test signal(s) 154 from ATE 102), GPIO (such as a peripheral input), or any other signal that is not dependent on keeping within the clock cycle of IUT 104. Input signal 552 does not need to be a lower speed signal, however. Other speed signals may be used as will be recognized by one skilled in the relevant art(s).

### An Alternative Exemplary Embodiment of Combined Pad Functionality

FIG. 5 depicts low pass filter 518 as being in series with high pass filter 516. In this configuration, the high frequency input signal 552 is extracted by high pass filter 516 while the low frequency input signal 550 does not pass through to recovery logic 508, instead reaching low pass filter 518 where any remaining high frequency transients from input signal 552 are removed. As an alternative, the filters may be situated to branch from a common node.

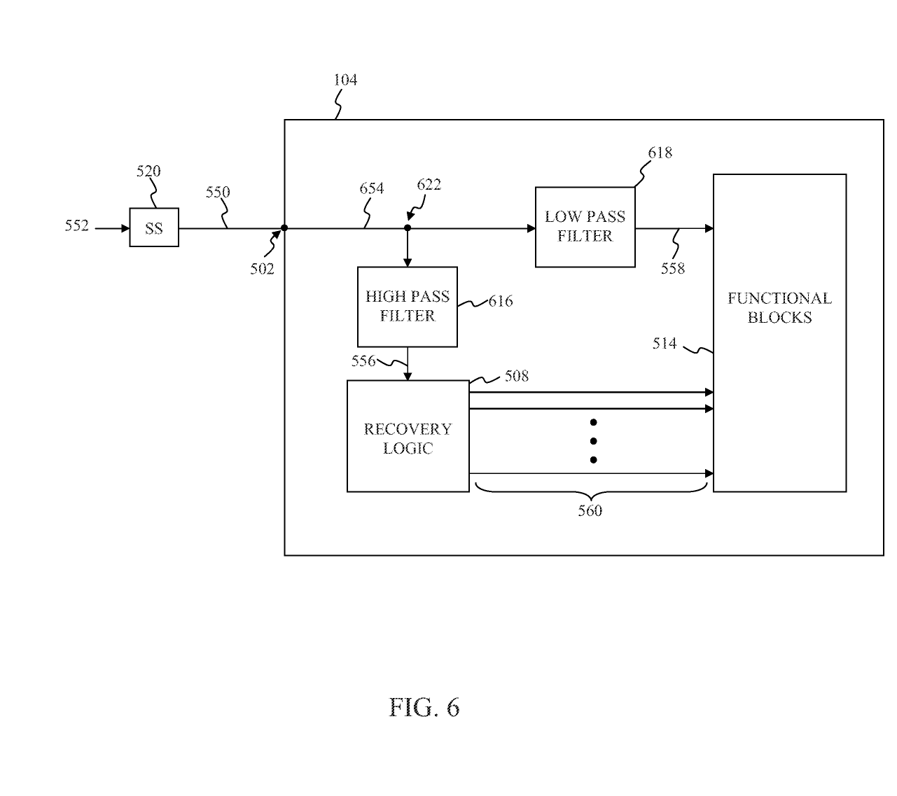

FIG. 6 illustrates an alternative embodiment for the third exemplary embodiment depicted in FIG. 5, as discussed above. In FIG. 6, high pass filter 616 and low pass filter 618 branch off of common node 622. High frequency input signal 552 and low frequency signal 550 both enter IUT 104 through combined pad 502, depicted as combined signal 654. In this configuration, the combined signal 654 reaches common node 622 and enters both high pass filter 616 and low pass filter 618. High pass filter 616 allows the high frequency input signal 552 component to pass as input A/C signal 556, which is then received by recovery logic 508 as discussed above regarding FIG. 5. The low frequency input signal 550 component of combined signal 654 is not allowed to pass through high pass filter 616. The recovery logic 508 includes circuitry necessary to convert the input A/C signal 556 to logic signals 560 that are then passed on to the appropriate blocks within the functional blocks 514.

The combined signal 654 also enters low pass filter 618 at approximately the same time that it enters high pass filter 616. In low pass filter 618, the low frequency input signal 550 component is allowed to pass as clean input signal 558. The high frequency input signal 552 component is not allowed to pass through low pass filter 618, preventing any corruption of the clean input signal 558 when it is passed on to the appropriate blocks within the functional blocks 514.

As already indicated, input signal 550 may be any one of a variety of types of signals, such as power, ground, or dedicated signals. In essence, FIGS. 5 and 6 depict sending what is typically a low speed (high frequency) input signal 552 across combined pad 502 that is generally used for other purposes.

### A Fourth Exemplary Embodiment of Combined Pad Functionality

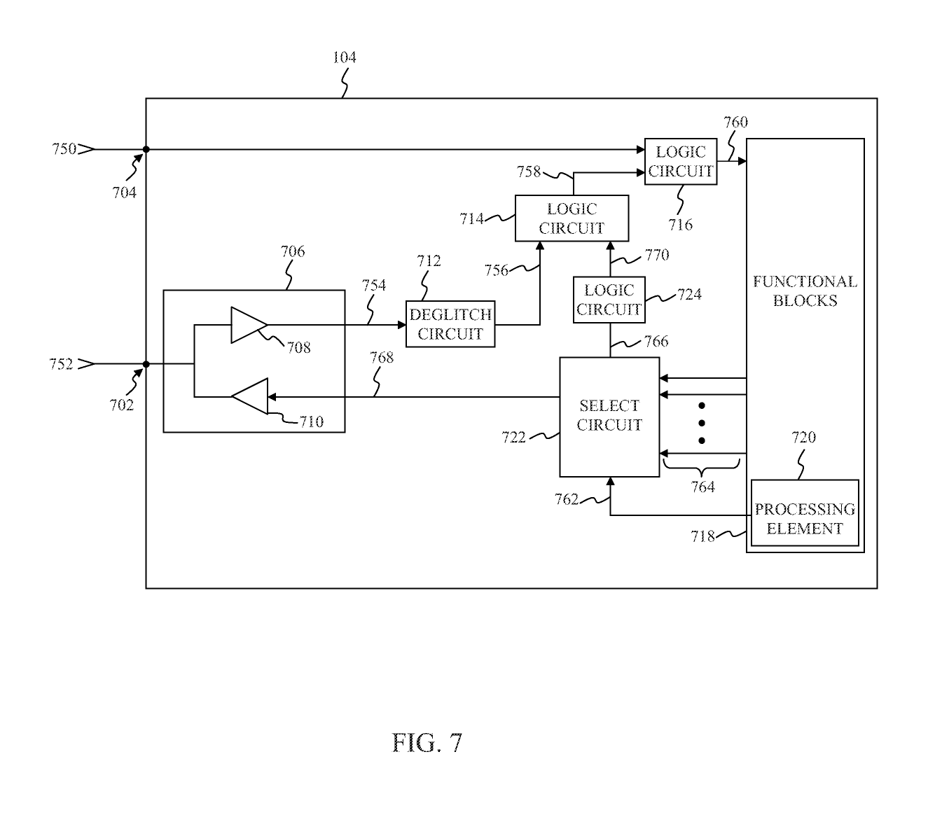

Instead of using the power, ground, or data signal pads of IUT 104 to combine pad functionality, a reset pad of IUT 104 may be reused to output data as well. FIG. 7 illustrates a block diagram of a combined functionality reset pad configuration on an integrated circuit according to a fourth exemplary embodiment of the present invention. While it will be recognized by one skilled in the relevant art(s) that the following discussion could apply to any number of integrated circuits, a SoC with an integrated power management unit (PMU) will be used by way of example. Integrating the PMU into the SoC, such as a baseband SoC, saves cost.

In this exemplary embodiment, IUT 104 includes two reset pads: PMU reset pad 704 and general reset pad 702. As indicated, PMU reset pad 704 does not need to be a dedicated reset pad for a PMU, but may be a dedicated reset pad for any one of a number of functional blocks within IUT 104. When reset pad 704 operates as the dedicated reset pad for a PMU within IUT 104, the PMU typically passes on the reset signal to the entire system. Consequently, the entire IUT 104 does not actually require a dedicated reset pad, since a reset signal 750 to reset pad 704 would subsequently send the rest of the IUT 104 into reset.

In such a configuration, however, there is the risk that the PMU may not be operating properly and therefore would not pass on the reset signal 750 to the rest of the IUT 104. To mitigate the risk of such an occurrence, a second general reset pad 702 may be included that combines other functionality as well. IUT 104 is configured to receive a general reset signal 752 through general reset pad 702, as will be described below, that will place the entire IUT 104 into reset. The added ability to use general reset pad 702 for other purposes reduces the overall cost of the IUT 104 while still reducing the overall risk of system restart failure. An example of operation is described below.

General reset signal 752 is sent across general reset pad 702. Pad circuitry 706 internal to the IUT 104 includes an input driver 708 and an output driver 710. The pad circuitry 706 may include a weak pull-up element, such as a resistor, which is not depicted in FIG. 7. This eliminates the need for any external components on the IUT 104. A pull-down element may be added for situations where the IUT 104 needs to be debugged with an external reset.

Input driver 708 receives general reset signal 752, which it outputs as signal 754. signal 754 enters deglitch circuit 712, which removes any unwanted nose from the signal. Deglitch circuit 712 outputs the signal 754 as clean signal 756, which enters logic circuit 714. The other input to the logic circuit 714 is reset control signal 770, as will be discussed below. Logic circuit 714 may be of any type known to one skilled in the relevant art(s), such as, for example, an OR gate. When logic gate 714 is configured as an OR gate, the reset signal will only pass through when the reset control signal 770 is the same value.

Logic circuit 714 outputs general internal reset signal 758, which as indicated above is only asserted when the reset control signal 770 is the same value as the clean signal 756, which is used to represent an asserted general reset signal 752. General internal reset signal 758 is input into logic circuit 716. Logic circuit 716 also receives the reset signal 750 across reset pad 702, in this example a PMU-specific reset signal. Logic circuit 716 may be, for example, an exclusive-NOR gate, which will select a reset signal when either signal 750 or 758 is asserted. If either reset signal 750 or 758 is asserted, logic circuit 716 outputs final reset signal 760 to the functional blocks 718.

IUT 104 includes circuitry that enables it to reuse general reset pad 702 as an output pad, for example a General Purpose Output (GPO) pad. The circuitry includes a select circuit 722, such as a multiplexer, which receives functional inputs 764 from one or more blocks from the functional blocks 718. The select circuit 722 receives select signal 762 from a processor 720, which may be any kind of processor or controller capable of outputting a select signal. The select circuit 722 outputs data signal 768, which is the selected functional input from the functional inputs 764 received from the functional blocks 718. The select circuit 722 also outputs a logic control signal 766 which enters logic circuit 724. Logic circuit 724 may be, for example, an OR gate. Logic control signal 766 is used to indicate when IUT 104 seeks to use general reset pad 702 as a GPO pad. Logic circuit 724 outputs reset control signal 770 to logic circuit 714.

The logic control signal 768 is used to control when the IUT 104 uses general reset pad 702 as a reset and when it uses general reset pad 702 as a GPO pad. When the IUT 104 seeks to output data through general reset pad 702, it asserts the logic control signal to the opposite logic value used for an asserted reset signal. Thus, for example, if general reset signal 752 is asserted low, select circuit 722 will assert the logic control signal high to lock the logic circuit 714 output (general internal reset signal 758) high.

Data signal 768 from the select circuit 722 is input into output driver 710, which drives the output onto the general reset pad 702 as GPO. The logic control signal 770 described above is useful when IUT 104 reuses the general reset pad 702 as a GPO pad because the data signal 768 typically includes a variety of values, such as a unique binary sequence of high and low values. If the general reset signal 752 is asserted low, then the IUT 104 would potentially enter reset any time that the data signal 768 included a low value. The logic control signal 766 prevents this by forcing the general internal reset signal to be opposite the logical value of the asserted general reset signal for as long as the IUT 104 has placed the general reset pad 702 in GPO mode.

While this embodiment of the present invention has been discussed as using multiple logic circuits, one skilled in the relevant art(s) will recognize that the results may be obtained by using more or fewer than the amount depicted here.

In the above manner, IUT 104 may reuse general reset pad 702 as a GPO pad while still retaining the ability to reset the system through reset pad 704. General reset pad 702 becomes, in this example, a failsafe reset for situations when the integrated PMU does not work and fails to pass on the reset signal 750 to the rest of the IUT 104.

### An Exemplary Embodiment of a Method for Utilizing Combined Pad Functionality

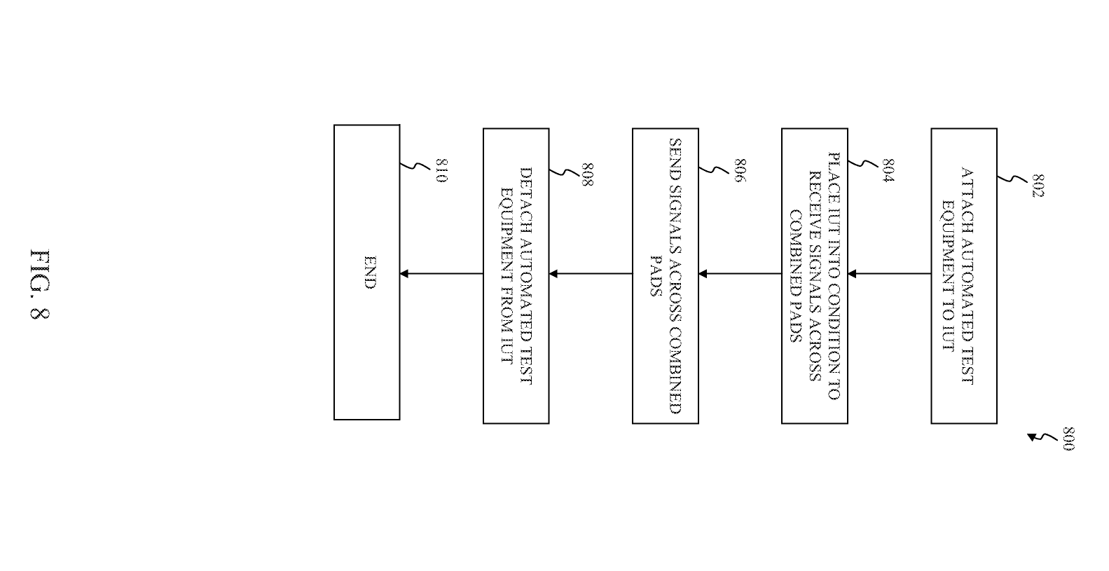

The following discussion describes the steps in FIG. 8. Method 800 illustrates a method of utilizing the combined functionality pads on an integrated circuit according to an exemplary embodiment of the present invention.

At step 802, a user attaches ATE 102 to IUT 104, which connects test mode signal 150, test signal(s) 154, and response test signal(s) 152. As an alternative, step 802 may involve an environment besides testing environment 100, such as connecting IUT to another device or integrated circuit.

At step 804, the IUT 104 is placed into condition to receive signals across the combined pad(s). For example, if IUT 104 is configured according to the first exemplary embodiment in FIG. 3 above, a user will close jumper 316 so that the combined pad 302 is tied directly to ground. Since IUT 104 in FIG. 3 enters test mode with the input 350 is asserted low, IUT 104 is now ready to receive and respond to test signal(s) 154. As another example, if IUT 104 is configured according to the second exemplary embodiment in FIG. 4 above, a user will restart the IUT 104 to place switch 408 into its default off state. This may alternatively be accomplished by turning switch 408 off during operation by a command from processor that controls switch 408.

At step 806, signals are sent across the connected combined pads to the IUT 104. Where the situation arises, signals are generated and returned across either dedicated pads, or through a combined pad as, for example, depicted in FIG. 7 above.

At step 808, the ATE 102, or another device or integrated circuit, is then detached from IUT 104, and the method ends at step 810.

### CONCLUSION

It is to be appreciated that the Detailed Description section, and not the Abstract section, is intended to be used to interpret the claims. The Abstract section may set forth one or more, but not all exemplary embodiments, of the present invention, and thus, are not intended to limit the present invention and the appended claims in any way.

The present invention has been described above with the aid of functional building blocks illustrating the implementation of specified functions and relationships thereof. The boundaries of these functional building blocks have been arbitrarily defined herein for the convenience of the description. Alternate boundaries may be defined so long as the specified functions and relationships thereof are appropriately performed.

It will be apparent to those skilled in the relevant art(s) that various changes in form and detail can be made therein without departing from the spirit and scope of the invention. Thus the present invention should not be limited by any of the above-described exemplary embodiments, but should be defined only in accordance with the following claims and their equivalents.

What is claimed is:

1. An integrated circuit in a testing environment, comprising:
an input pad configured to receive a first signal;
a switch configured to connect and disconnect a functional block from the first signal received at the input pad;
a power source connected to the functional block; and
an extraction module configured to extract data from a second signal received at the input pad;
wherein the first signal is power or ground and the second signal is a test signal.

2. The integrated circuit of claim 1, wherein the input pad is configured to receive the second signal when the switch has disconnected the functional block from the first signal received at the input pad.

3. The integrated circuit of claim 2, wherein the power source is configured to supply a third signal to the functional block when the switch has disconnected the functional block from the first signal.

4. The integrated circuit of claim 2, wherein the functional block is a one-time programmable memory and the second power source is a low dropout regulator.

5. The integrated circuit of claim 2, wherein the extraction module is a digital decoding circuit configured to output the extracted data from the second signal to a plurality of functional blocks within the integrated circuit.

6. An integrated circuit, comprising:
an input pad configured to receive a first signal;
a low pass filter configured to extract the first signal;
an extraction module configured to extract data from a second signal received at the input pad; and
a high pass filter configured to recover the second signal that is received at the input pad,
wherein the extraction module is configured to recover a digital signal from the second signal recovered from the high pass filter; and
wherein the second signal has a higher frequency than the first signal.

7. The integrated circuit of claim 6, wherein the high pass filter is followed in series by the low pass filter.

8. The integrated circuit of claim 6, wherein the high pass filter and the low pass filter share a common node connected to the input pad.

9. The integrated circuit of claim 6, wherein the second signal comprises an analog signal operating at tens to hundreds of Gigahertz.

10. The integrated circuit of claim 9, wherein the second signal is a test signal.

11. The integrated circuit of claim 9, wherein the first signal is power supplied by the power source, and wherein the first signal is operating at less than one Gigahertz.

12. The integrated circuit of claim 9, wherein the first signal is a data signal supplied by a data source.

13. An integrated circuit, comprising:
an input pad configured to receive a first signal;
a first voltage regulator configured to output a first regulated voltage; and
a second voltage regulator configured to output a second regulated voltage;
wherein the first signal is supplied by a decoupling capacitor attached to the input pad,
wherein the input pad is configured to be interchangeably attached to the decoupling capacitor and a ground source to supply a second signal at the input pad, and
wherein the integrated circuit is configured to enter a test mode when the input pad is attached to the ground source.

14. The integrated circuit of claim 13, further comprising:
a selection module configured to select between the first regulated voltage and the second regulated voltage and output a selected voltage; and
a functional block configured to receive the selected voltage.

15. The integrated circuit of claim 14, wherein the selection module is configured to select the second regulated voltage when the input pad is attached to the ground source.

16. The integrated circuit of claim 14, wherein:
the integrated circuit is a power management unit;
the functional block is a one-time programmable memory;
the first voltage regulator is a low dropout regulator;
the second voltage regulator is a low dropout regulator; and
the selection module comprises a multiplexer.

17. An integrated circuit, comprising:
a first pad configured to receive a first signal;
a second pad configured to receive a second signal;
a plurality of functional blocks within the integrated circuit configured to provide a plurality of data signals;
a selection module configured to receive the plurality of data signals, select a third signal from among the plurality of data signals, and output the selected third signal and a control signal; and
a logic module configured to receive the control signal and block second signal when the control signal is asserted.

18. The integrated circuit of claim 17, further comprising:
a deglitch circuit configured to remove noise from the second signal; and
a pad circuit configured to drive the second signal to the deglitch circuit and drive the third signal to the second pad as an output.

19. The integrated circuit of claim 17, wherein the logic module comprises:
a first logic circuit configured to pass through the control signal from the selection module;
a second logic circuit configured to receive the second signal from the deglitch circuit and the control signal from the first logic circuit, and output the control signal when the control signal is asserted, and output the second signal when the control signal is not asserted; and
a third logic circuit configured to receive the first signal and the output from the second logic circuit, and output the first signal when asserted or the second signal when asserted.

20. The integrated circuit of claim 17, wherein:
the first signal is a power management unit reset signal;
the second signal is a general purpose reset signal; and
the third signal is a general purpose output data signal.
